(19) United States
(12) Patent Application Publication
(10) Pub. No.: US 2009/0098460 A1
(43) Pub. Date: Apr. 16, 2009

(54) NEGATIVE PLATE FOR LITHIUM ION BATTERIES AND A METHOD OF PREPARING THE SAME

(76) Inventors: Xiaoming Kang, Shenzhen (CN); Guihai Liang, Shenzhen (CN); Zhong Li, Shenzhen (CN); Zhanfeng Jiang, Shenzhen (CN); Long He, Shenzhen (CN)

Correspondence Address: BRINKS HOFER GILSON & LIONE, P.O. BOX 10395, CHICAGO, IL, 60610, US

(21) Appl. No.: 12/249,631

(22) Filed: Oct. 10, 2008

(30) Foreign Application Priority Data
Oct. 11, 2007 (CN) CN200710152574.0

(51) Int. Cl. H01M 4/02; H01M 4/38; H01M 6/00; C23C 14/14; C23C 14/02; C23C 14/30

(52) U.S. Cl. 429/220; 429/209; 429/229; 429/231.6; 429/231.5; 427/597; 427/532

(57) ABSTRACT

In one aspect, a negative plate for a battery comprises a negative current collector coated with a negative active material. The negative current collector comprises a conductive non-woven fabric. In another aspect, a method for preparing a negative plate for a battery comprises coating a negative active material onto a negative current collector. The negative current collector comprises a conductive non-woven fabric. In yet another aspect, a battery comprises a negative plate. The negative plate comprises a negative current collector coated with a negative active material. The negative current collector comprises a conductive non-woven fabric.

The present application claims priority to Chinese Patent Application No. CN200710152574.0, filed Oct. 11, 2007, the entirety of which is hereby incorporated by reference.

### FIELD OF THE DISCLOSURE

The present disclosure relates to a negative plate for batteries and a method of preparing the same. More particularly, the present disclosure relates to a negative plate for lithium ion batteries and a method of preparing the same.

### BACKGROUND OF THE DISCLOSURE

Recently, as a result of the development of high technologies in the electronic industry, miniaturized and light electronic devices can be easily provided, which leads to a more and more wide use of portable electronic devices. Lithium ion batteries become a first-choice energy source for these portable devices due to their advantages of high discharge voltage, high energy density and long cycle time.

The electrical core of a lithium ion battery comprises a positive plate, a negative plate, a separator and an electrolyte. The performance of the negative plate has a large effect on the performance of the lithium ion battery. However, the volume of the lithium ion battery will swell during Li⁺ intercalation and deintercalation of the negative material on the negative plate. At present, many lithium ion batteries use LiCoO₂ as the positive electrode and graphite as the negative electrode. There is no obvious volume change during Li⁺ intercalation and deintercalation of LiCoO₂. However, there is a 1.2 time volume change during the Li⁺ intercalation and deintercalation of graphite. Although this level of volume change may be acceptable, the specific capacity of the lithium ion batteries using these materials is low and thus limits the further applications of these batteries.

Si and Sn as negative active materials can form an alloy with lithium which leads to a high specific capacity. Sn has a theoretical capacity of 900 mAh/g, while Si has a theoretical capacity of 4200 mAh/g. However, there is a huge volume change before and after Li⁺ intercalation and deintercalation. Complete Li⁺ intercalation will cause about a 4 time volume swell. Such a huge volume change can cause separation of the negative active materials from and cracking of the negative active materials on the negative plate. Thus the batteries using Si and Sn as negative active materials typically have a poor cycle performance.

Therefore, it is desirable to develop negative plates which can achieve high cycle performance of the batteries.

### SUMMARY OF THE DISCLOSURE

In one aspect, a negative plate for a battery comprises a negative current collector coated with a negative active material. The negative current collector comprises a conductive non-woven fabric.

In another aspect, a method for preparing a negative plate for a battery comprises coating a negative active material onto a negative current collector. The negative current collector comprises a conductive non-woven fabric.

In yet another aspect, a battery comprises a negative plate. The negative plate comprises a negative current collector coated with a negative active material. The negative current collector comprises a conductive non-woven fabric.

### DESCRIPTION OF THE DRAWINGS

FIG. 1 is a top view of the surface of the negative plate which was prepared in example 1 under 500-time amplification SEM.

FIG. 2 is a sketch map of plating the negative active materials onto the negative current collector while preparing the negative plate as described in example 2.

FIG. 3 is a sketch map of plating the negative active materials onto the negative current collector while preparing the negative plate as described in example 3.

FIG. 4 is a sketch map of plating the negative active materials onto the negative current collector while preparing the negative plate as described in example 4.

### DETAILED DESCRIPTION OF THE PREFERRED EMBODIMENTS

According to one embodiment of the present disclosure, a negative plate is provided for lithium ion batteries. The negative plate comprises a negative current collector and a negative active material coated on the negative current collector. The negative current collector comprises conductive non-woven fabric.

The conductive non-woven fabric is a non-woven fabric that is plated with a conductive metal. Thus it has good conductive performance. During Li⁺ intercalation and deintercalation, the conductive non-woven fabric is able to adapt to the volume changes of the negative active materials which enhance the cycle performance of the lithium ion batteries. Conductive non-woven fabric is commercially available, a suitable example is ECUWFO716 manufactured by Marubeni.

To more effectively prevent the negative active materials' separating and cracking caused by the volume change during Li⁺ intercalation and deintercalation, preferably, the negative current collector surface comprises one or more coated and uncoated areas.

The coated area is an area that is coated with the negative active materials. The uncoated area is an area that is not coated with the negative active materials.

According to one embodiment of the present disclosure, the coated areas are separated by the uncoated areas. The alternately distributed negative active materials can more effectively prevent the negative active materials' separating and cracking caused by the volume change during Li⁺ intercalation and deintercalation.

According to one embodiment of the present disclosure, the proportion of the coated and uncoated area of the negative current collector may vary in a large range. Preferably, the one or more coated areas account for about 50-98% of the total surface area of the negative current collector. More preferably, the one or more coated areas account for about 80-90% of the total surface area of the negative current collector. Preferably, the coated area is about 0.01-25 mm². More preferably, each of the coated areas is about 0.01-25 mm². Under the above conditions, it is more effective to prevent the separating and cracking effects to the negative plate caused by the volume change during Li⁺ intercalation and deintercalation, which in turn enhances the cycle performance of the prepared lithium ion batteries.

According to one embodiment of the present disclosure, the coating amount of the negative active materials should be sufficient to achieve a coated area with a single-side thickness of about 1-20 μm, and preferably, of about 5-10 μm.

The coated area may assume any suitable shape. For example, it can be one or more shape selected from rectangular, polygonal, circular, and semicircular. Preferably, the shape of the coated area is a regular polygon. Preferably, each coated area is equivalent and is distributed equally. Or the shape of the coated area is a strip. Preferably, each coated area is equivalent and is distributed equally. Under the above conditions, the negative plate has sufficient contact with the electrolyte. It is more effective to prevent the separating and cracking effects to the negative plate caused by the volume change during Li⁺ intercalation and deintercalation. Furthermore, with a higher coating amount of the negative active materials on the negative current collector, the specific capacity is enhanced.

Any suitable negative active material can be used. For example, any commonly used negative active materials in the pertinent field can be used. Preferably, the negative active material comprises a first component or a mixture of a first component and a second component. The first component is preferably selected from the group consisting of Si, Sn, Ge, Zn, Al, Mg, and a combination thereof. The second component is preferably selected from the group consisting of Co, Ti, B, Ni, Cu, Zr, Au, and a combination thereof. More preferably, the negative active material is the mixture of the first component and the second component, wherein the second component is capable of buffering the volume change of the first component during the Li⁺ intercalation and deintercalation. Thus the cycle performance of the lithium ion batteries can be further enhanced.

The content of the first component and the second component may vary in a large range. Preferably, based on the total weight of the negative active material, the content of the first component is about 20-99% of the total weight, and the content of the second component is about 1-80% of the total weight.

According to a second embodiment of the present disclosure, a method of preparing the negative plates of lithium ion batteries is provided. The negative active material is used as an evaporator source. The negative active material is evaporated and plated onto the negative current collector. Any suitable evaporation method can be used. Preferably, the evaporation method is an electron beam vacuum evaporation plating method. The negative current collector may comprise conductive non-woven fabric.

According to one embodiment of the present disclosure, in order to obtain a negative plate with better cycle performance, preferably, the negative active material is evaporation plated onto the negative current collector to form one or more coated and uncoated areas onto the negative current collector. In order to form one or more coated and uncoated areas on the negative current collector, the negative current collector is covered with a mask before evaporation plating. The uncoated area is produced when the mask is removed after evaporation plating. For example, the negative current collector may be covered with a meshed net. During evaporation plating, the vapor of the negative active material can only deposit to the negative current collector through the meshes of the meshed net. After evaporation, the meshed net is removed to form one or more coated and uncoated areas on the negative current collector. Alternatively, the negative active material can be evaporation plated to the negative current collector first. The uncoated area is produced when some of the negative active material is removed from the evaporation plated negative current collector. For example, some of the negative active material can be removed by laser etching or chemical etching. Preferably, the negative active material is removed according to a pre-determined pattern.

Any suitable conditions for electron beam vacuum plating can be used. For example, the condition for the electron beam vacuum plating in preparing a conventional lithium-ion battery negative plate can be used. In order to improve the efficiency of evaporation and keep negative current collector away from the effect of source of evaporation, preferably, the condition of the electron beam vacuum plating is under a vacuum pressure of below about 1×10⁻² Pa, an electron beam current of about 50-500 MA, and a voltage of about 3-12 kV. The negative current collector has an about 30-150 cm distance from the evaporation source. The evaporation time is about 5-50 minutes. More preferably, the condition of the electron beam vacuum plating is under a vacuum pressure of about 1×10⁻⁴-5×10⁻³ Pa, an electron beam current of 70-120 mA, and a voltage of electron gun of 5-8 KV. The negative current collector has an about 50-100 cm distance from the evaporation source. The evaporation time is about 5-50 minutes. Under normal circumstances, the current of the described electron beam is relevant to the current and voltage of the filament. Thus the electron beam current can be controlled in the above range by controlling the filament's voltage and current. The equipment for electron beam vacuum plating is commercially available. For example, the electron beam vacuum evaporation device of the Model HVC-800DA from Korea First Vacuum, and the Model of TS-100DT from Tengsheng Vacuum can be used.

In the process of electron beam vacuum plating, when the average particle diameter of the negative active material is small, it is easy for the negative active material particles to be bombarded away by the electron beam, causing a loss of the evaporation source. When the average particle diameter of the negative active material is large, it is difficult for the negative active material particles to be filled into a crucible smoothly. Therefore, preferably, the average particle diameter of the negative active material is about 0.1-20 mm, and more preferably about 1-5 mm. The above average particle diameter can be obtained through sifting.

The method according to one embodiment of the present invention further comprises using ion beam to pretreat the negative current collector before vacuum plating. The vacuum pressure is about 0.1-10 Pa, the ion beam voltage is about 150-300 V, the current is about 0.1-0.5 A, and the pretreating time is about 1-20 minutes. The pretreatment can remove various impurities on the negative current collector, and thus the negative active material can be coated to the negative current collector more closely.

### EXAMPLE 1

This example illustrates a method of preparing the negative plate for lithium ion batteries.

(1) Preparation of a Negative Plate:

About 100 parts by weight of the raw material silicon (Oryx Sputtering Targets Limited Co., the average particle diameter is about 2 mm) was put into the crucible of a vacuum coating instrument (Tengsheng Vacuum Production, TS-100DT) as an evaporation source. A conductive non-woven fabric (Marubeni Ltd. Co., ECUWF0716) was horizontally fixed immediately above the evaporation source within a distance of about 80 cm. The instrument was then vacuumized to maintain the pressure when it dropped to about 1×10⁻³ Pa. Evaporation stated when the electron beam bombarded the evaporation source. The filament voltage was about 75 V, the current was about 1.1 A, the electron beam current was about 70 mA, the electron gun voltage was about 7.5 kV, and the evaporation time was about 10 minutes. Substantially all of the raw material silicon was plated onto the conductive non-woven fabric. The conductive cross-section of non-woven fabric was observed by Scanning Electron Microscope (Japan JEOL Company, JSM-5610LV). The single-side thickness of the coating on the conductive non-woven fabric was about 5 microns. After vacuum plating, the negative plate was cooled under the vacuum condition, then ventilated and removed from the vacuum coating instrument. The negative plate was cut by a slitter into negative plates B1 with the single size of about 44 mm×about 31.5 mm.

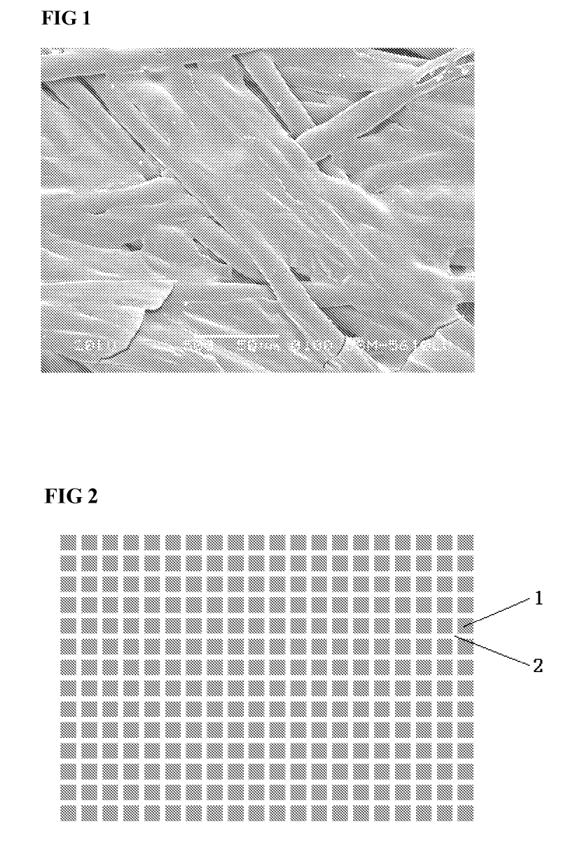

FIG. 1 illustrated the negative plate under 500 times amplification of the SEM (Japan JEOL company, JSM-5610LV).

(2) Preparation of the Positive Plate:

About 100 parts by weight of LiFePO₄ (from Tianjin Xiandao Company, with the particle diameter of about 0.5 microns), about 5 parts by weight of binder polyvinylidene fluoride (PVDF) and about 8 parts by weight of conductive material acetylene black were added into about 80 parts by weight N-Methyl Pyrrolidone (NMP), and then mixed in a vacuum mixer to obtain the slurry of the positive active materials. The slurry was plated onto a broad width aluminum foil with a width of about 400 mm and a thickness of about 20 microns. The foil with the plated slurry was then dried in vacuum at about 100° C., and cut by a slitter to obtain the positive plate A1 with the single size of about 43.5 mm×about 31 mm.

(3) Battery Assembly:

LiPF₆, ethylene carbonate (EC) and diethyl carbonate were mixed to obtain a LiPF₆ solution with a concentration of about 1.0 mol/L (volume ratio of EC/DEC was about 1:1). The LiPF₆ solution is the non-water electrolyte. The positive plate obtained from the above section (2), polyethylene(PE) separation membrane, and the negative plate obtained from the above section (1) were assembled to produce an array of electrodes. The array of electrodes was placed into a steel shell of battery with an opening end. About 4.0 g/Ah of the above non-water electrolyte was injected into the steel shell. After sealing, the lithium-ion battery D1 was obtained.

### COMPARATIVE EXAMPLE 1

A preparation method similar to example 1 was used to prepare the comparative lithium-ion battery. The difference was to replace the conductive non-woven fabric of example 1 with copper foil (from Guangdong Meiyan with a roughness of about 0.8 microns) as the negative current collector to prepare comparative lithium-ion battery CD1.

### EXAMPLE 2

This example illustrates a preparing method of the negative plate for lithium ion batteries.

(1) Preparation of the Negative Plate:

About 100 parts by weight of the raw material silicon (Oryx Sputtering Targets Limited Co, the average particle diameter is about 2 mm) was added into the crucible of a vacuum coating instrument (Tengsheng Vacuum Production, TS-100DT) as an evaporation source. A conductive non-woven fabric (Marubeni Ltd. Co., ECUWF0716) was horizontally fixed immediately above the evaporation source with a distance of about 80 cm. The instrument was then vacuumized to maintain the pressure when it dropped to about 1×10⁻⁵ Pa. Evaporation started when the electron beam bombarded the evaporation source. The filament voltage was about 75 V, the current was about 1.1 A, the electron beam current was about 150 mA, the electron gun voltage was about 10 KV, and the evaporation time was about 5 minutes. Substantially all of the raw material silicon was plated onto the conductive non-woven fabric. The conductive cross-section of non-woven fabric was observed by Scanning Electron Microscope (Japan JEOL Company, JSM-5610LV). The single-side thickness of the coating on the conductive non-woven fabric was about 10 microns. After vacuum plating, the negative plate was cooled under the vacuum condition, then ventilated and removed from the instrument. Thus the negative plate with one or more coated and uncoated areas was obtained. Each coated area was about 0.25 mm². The sketch map of the evaporation plating was showed in FIG. 2. On the negative current collector, the total coated surface areas accounted for about 85% of the total surface area of the negative current collector. The negative plate was cut by the slitter into negative plates B2 with the single size of about 44 mm×about 31.5 mm.

(2) Preparation of the Positive Plate:

About 100 parts by weight of LiFePO₄ (from Tianjin Xiandao Company, with the particle diameter of about 0.5 microns), about 5 parts by weight of binder polyvinylidene fluoride (PVDF), and about 8 parts by weight of the conductive material acetylene black were added into about 80 parts by weight N-Methyl Pyrrolidone (NMP), and then mixed in a vacuum mixer to obtain a slurry of the positive active materials. The slurry was plated onto a broad width aluminum foil with a width of about 400 mm, and a thickness of about 20 microns. The foil with the plated slurry was then dried under vacuum at about 100° C., and cut by a slitter to obtain the positive plate A2 with the single size of about 43.5 mm×about 31 mm.

(3) Battery Assembly:

LiPF₆, ethylene carbonate (EC), and diethyl carbonate were mixed to form a LiPF₆ solution with a concentration of about 1.0 mol/L (volume ratio of EC/DEC was about 1:1). The LiPF₆ solution was the non-water electrolyte. The positive plate obtained from the above section (2) polyethylene (PE) separation membrane, and the negative plate obtained from above section (1) were assembled to form an array of electrodes. The array of electrodes was placed into a steel shell of battery with an opening end. About 4.0 g/Ah of the above non-water electrolyte was injected into the steel shell. After sealing, the lithium-ion battery D2 was obtained.

### EXAMPLE 3

A preparation method of the negative plate of lithium-ion battery according to one embodiment of the present invention is illustrated in this example.

(1) The Preparation of the Negative Plate:

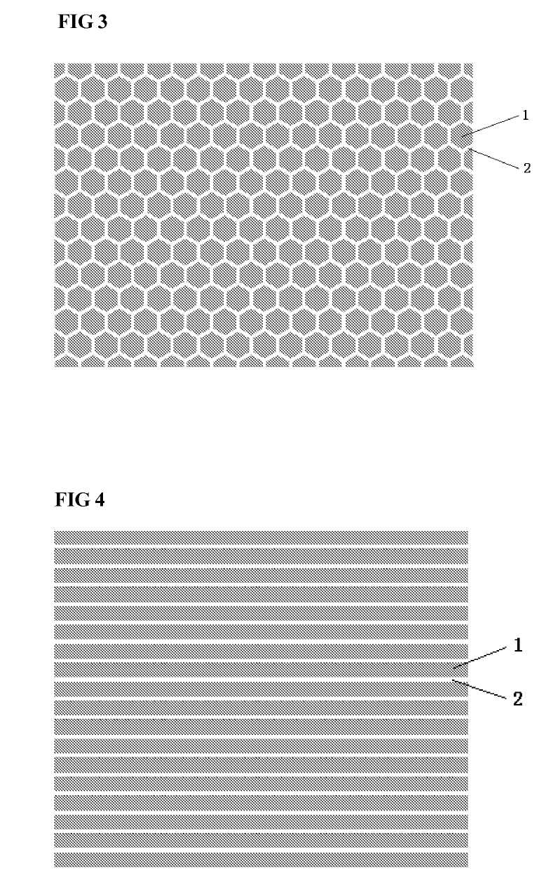

About 80 parts by weight of silicon (Oryx Sputtering Targets limited company, average diameter of the particle is about 2 mm) and 20 parts by weight of cobalt (TGT Optoelectronic Technology Limited Company, average diameter of the particle is about 3 mm) were added into the crucible of a vacuum coating instrument (from TengSheng Vacuum, TS-100DT) to form an evaporation source. A conductive non-woven fabric (Marubeni Limited Company, ECUWF0716) was fixed horizontally immediately above the evaporation source with a distance of about 50 cm. A layer of mesh screen was placed on the non-woven fabric. The instrument was then vacuumized. When the pressure dropped to about 10 pa, the ion beam was started to bombard the conductive non-woven fabric for about 15 minutes. The voltage of the ion beam was about 250 v and the current was about 0.5 A. When the pressure dropped to about 1×10⁻² pa, the pressure was maintained. The ion beam was started to bombard the evaporation source, and then begin to plate with evaporation. The voltage of filament was about 75 V and the current was about 1.1 A, the current of the ion beam was about 400 mA, the voltage of the electron gun was about 8 kV, the time for evaporation plating was about 5 minutes in order to plate the silicon and cobalt onto the conductive non-woven fabric. The cross section of the non-woven fabric was observed by scan electron microscope (JEOL Company of Japan). The thickness of the single-side of the coating on the conductive non-woven fabric was about 6 microns. After plating, the negative plate was cooled under the vacuum condition, then ventilated and removed form the instrument to produce the negative plate with one or more coated and uncoated areas. Each coated area was about 2.5 mm². The sketch map of the evaporation plating was illustrated in FIG. 3. On the negative current collector, the total coated surface area accounted for about 70% of total surface area of the negative current collector. The negative plate was cut on the slitter into negative plates B3 with the single size of about 44 mm×about 31.5mm.

(2) The Preparation of Positive Plate:

About 100 parts by weight LiFePO₄ (from Tianjin Xiandao Company, with the particle diameter of about 0.5 micron), about 5 parts by weight binder of polyvinylidene fluoride (PVDF), and about 8 parts by weight conductive material of acetylene black were added into about 80 parts by weight N-methyl-2-pyrrolidone, and then mixed in a vacuum mixer to produce a positive active material slurry. The positive active material slurry was evaporation plated onto a broad width aluminum foil with a width of about 400 mm and a thickness of about 20 microns. After evaporation plating, the foil with the plated slurry was then dried in vacuum at about 100° C., and was cut by the slitter into positive plates A3 with a single size of about 43.5 mm×about 31 mm.

(3)Battery Assembly:

LiPF₆, ethylene carbonate (EC) and diethyl carbonate were mixed to obtain a LiPF₆ solution with a concentration of about 1.0 mol/L (volume ratio of EC/DEC was about 1:1). The LiPF₆ solution was the non-water electrolyte. The positive plate obtained from the above section (2) polyethylene(PE) separation membrane, and the negative plate obtained from the above section (1) were assembled to form an array of electrodes. The array of electrodes was placed into a steel shell of battery with an opening end. About 4.0 g/Ah of the above non-water electrolyte was injected into the steel shell. After sealing, the lithium-ion battery D2 was obtained.

### EXAMPLE 4

This example illustrates a preparation method of the negative plate of lithium-ion battery according to one embodiment of the present invention.

(1) The Preparation of the Negative Plate:

About 40 parts by weight of silicon (Oryx Sputtering Targets Limited Company, average diameter of the particle is about 2 mm), about 20 parts by weight of tin (TGT Optoelectronic Technology Limited Company, average diameter of the particle is about 2.5 mm) and about 40 parts by weight of titanium (TGT Optoelectronic Technology limited company, average diameter of the particle is about 2.5 mm) were added into the crucible of a vacuum coating instrument (from TengSheng Vacuum, TS-100DT) to form an evaporation source. A conductive non-woven fabric (Marubeni Limited Company, ECUWF0716) was fixed horizontally immediately above the evaporation source with a distance of about 80 cm. A layer of mesh screen was placed on the non-woven fabric. The instrument was then vacuumized. When the pressure dropped to about 10 pa, the ion beam was started to bombard the conductive non-woven fabric for about 5 minutes. The voltage of the ion beam was about 200 V and the current was about 0.2 A.

When the pressure dropped to and maintained at about 1×10⁻⁵ pa, the ion beam was started to bombard the evaporation source, and then evaporation plating is started. The voltage of filament was about 75 V and the current was about 1.1 A, the current of the ion beam was about 400 mA, the voltage of the electron gun was about 10 kV, and the time for evaporation plating was about 20 minutes to plate the silicon and cobalt material onto the conductive non-woven fabric. The cross section of the non-woven fabric was observed by scan electron microscope (JEOL Company of Japan). The single-side thickness of the coating on the conductive non-woven fabric was about 10 microns. After evaporation plating, the negative plate was cooled under the vacuum condition, then ventilated and removed from the instrument to produce the negative plate with one or more coated and uncoated areas. Each coated area was about 1 mm². The sketch map of the evaporation plating was illustrated in FIG. 4. On the negative current collector, the total coated surface areas accounted for about 60% of the total surface area of the negative current collector. The negative plate was cut on the slitter into negative plates B4 with the single size of about 44 mm×about 31.5 mm.

(2) The Preparation of Positive Plate:

About 100 parts by weight of LiFePO₄ (Tianjin Xiandao Company, with the particle diameter of about 0.5 micron), about 5 parts by weight of binder of polyvinylidene fluoride (PVDF), and about 8 parts by weight of the conductive material of acetylene black were added into about 80 weight by weight N-methyl-2-pyrrolidone, and then mixed in a vacuum mixer to obtain a positive active material slurry. The positive active material slurry was evaporation plated onto the broad width aluminum foil with a width of about 400 mm and a depth of about 20 microns. The foil with plated slurry was dried in vacuum at about 100° C., and thereafter was cut by the slitter into positive plates A4 with a single size of about 43.5 mm×about 31 mm.

(3)Battery Assembly:

LiPF₆, ethylene carbonate (EC) and diethyl carbonate were mixed to obtain a LiPF₆ solution with a concentration of about 1.0 mol/L (volume ratio of EC/DEC was about 1:1). The LiPF₆ solution was the non-water electrolyte. The positive plate obtained from the above section (2), polyethylene(PE) separation membrane, and the negative plate obtained from above section (1) were assembled to produce an array of electrodes. The array of electrodes was placed into a steel shell of battery with an opening end. About 4.0 g/Ah of the above non-water electrolyte was injected into the steel shell. After sealing, the lithium-ion battery D4 was obtained.

### EXAMPLES 5-8

Test of Cycle Performance:

The cycle performance of the lithium-ion battery D1-D4 obtained from Example 1-4 was tested. First, the battery was charged to about 3.8 V by a 1 C current. After the voltage reaches to about 3.8 V, the battery was charged by a constant voltage with a cut-off current of about 0.05 c. The battery was then set aside for about 5 minutes. Second, the battery was discharged to about 2.0 V by a 1 C current. The battery was then set aside for about 5 minutes. The above steps were repeated for 100 times to obtain the battery capacity of discharging to 2.0 V by a 1 C current after 100 cycles. The capacity maintenance rates of the battery before and after the cycling were calculated. The results are shown in Table 1.

### COMPARISON EXAMPLE 2

Test of Cycle Performance:

The cycle performance of lithium-ion battery CD1 obtained from Comparison Example 1 was tested by the testing method as in Example 5-8. The result is showed in Table 1.

TABLE 1

| | | Maintenance Rate of |
|---|---|---|
| Example # | Battery # | Capacity (%) |
| Example 5 | D1 | 85 |
| Example 6 | D2 | 90 |
| Example 7 | D3 | 94 |
| Example 8 | D4 | 95 |
| Comparison Example 2 | CD1 | 51 |

As shown in Table 1, according to one embodiment of the present invention, the maintenance rates of capacity of lithium-ion batteries D1-D4 obtained from Examples 1-4 reach up to about 85%, about 90%, about 94% and about 95%, respectively. However the maintenance rate of capacity of comparative lithium-ion battery CD1 obtained from Comparison Example 1 is only about 51%, which shows that the cycle performance of the lithium-ion battery comprising the negative plate according to embodiments of the present invention is improved.

In addition, according to one embodiment of the present invention, the maintenance rates of capacity of lithium-ion batteries D2-D4 with the negative plate having both coated area and uncoated area on the negative current collector obtained from Examples 2-4 are higher than that of lithium-ion battery D1 obtained from Example 1, which shows that alternatively distributed negative activity material is beneficial to further enhance the cycle performance of lithium-ion batteries.

Moreover, according to one embodiment of the present invention, the maintenance rates of capacity of lithium-ion batteries D3-D4 with the negative plate active material comprising a mixture of two components obtained from Examples 3-4 are higher than that of lithium-ion D2 obtained from Example 2, which shows that adding a second component is beneficial to further enhance the cycle performance of lithium-ion batteries.

Many modifications and other embodiments of the present disclosure will come to mind to one skilled in the art to which the present disclosure pertains having the benefit of the teachings presented in the foregoing description; and it will be apparent to those skilled in the art that variations and modifications of the present disclosure can be made without departing from the scope or spirit of the present disclosure. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

We claim:

1. A negative plate for a battery comprising:
a negative current collector coated with a negative active material, wherein the negative current collector comprises a conductive non-woven fabric.

2. The negative plate of claim 1, wherein the surface of the negative current collector comprises one or more coated areas coated with the negative active material, and one or more uncoated areas.

3. The negative plate of claim 2, wherein the coated areas are separated by the uncoated areas.

4. The negative plate of claim 2, wherein the total surface area of the coated areas is about 50-98% of the total surface area of the negative current collector.

5. The negative plate of claim 4, wherein the total surface area of the coated areas is about 80-90% of the total surface area of the negative current collector.

6. The negative plate of claim 2, wherein the coated area is about 0.01-25 mm².

7. The negative plate of claim 2, wherein the thickness of the coated area is about 1-20 μm.

8. The negative plate of claim 7, wherein the thickness of the coated area is about 5-10 μm.

9. The negative plate of claim 2, wherein the coated area has a shape selected from a group consisting of rectangular, polygonal, circular, and semicircular.

10. The negative plate of claim 1, wherein the negative active material comprises a first component selected from the group consisting of Si, Sn, Ge, Zn, Al, Mg, and combinations thereof.

11. The negative plate of claim 10, wherein the negative active material further comprises a second component selected from the group consisting of Co, Ti, B, Ni, Cu, Zr, Au, and combinations thereof.

12. The negative plate of claim 11, wherein, based on the total weight of the negative active material, the first component is about 20-99% of the total weight, and the second component is about 1-80% of the total weight.

13. A method for preparing a negative plate for a battery comprising:
coating a negative active material onto a negative current collector, wherein the negative current collector comprises a conductive non-woven fabric.

14. The method of claim 13, wherein the coating step comprises electron beam vacuum evaporation plating the negative active material onto the negative current collector.

15. The method of claim 14, wherein the negative active material is used as an evaporator source.

16. The method of claim 14, further comprising:
forming a masking layer on at least one surface area of the negative current collector prior to the electron beam vacuum evaporation plating step; and
removing the masking layer subsequent to the electron beam vacuum evaporation plating step to form one or more coated areas coated with the negative active material and one or more uncoated areas substantially corresponding to the masking layer.

17. The method of claim 14, further comprising:
removing the plated negative active material from at least one surface area of the negative current collector to form one or more coated areas coated with the negative active material and one or more uncoated areas substantially corresponding to the at least one surface area of the negative current collector where the negative active material is removed.

18. The method of claim 13, wherein the negative active material comprises a first component selected from the group consisting of Si, Sn, Ge, Zn, Al, Mg, and combinations thereof.

19. The method of claim 18, wherein the negative active material further comprises a second component selected from the group consisting of Co, Ti, B, Ni, Cu, Zr, Au, and combinations thereof.

20. The method of claim 19, wherein, based on the total weight of the negative active material, the first component is about 20-99% of the total weight, and the second component is about 1-80% of the total weight.

21. The method of claim 13, wherein the average particle diameter of the negative active material is about 0.1-20 mm.

22. The method of claim 21, wherein the average particle diameter of the negative active material is about 1-5 mm.

23. The method of claim 13, further comprising:
pretreating the negative current collector before coating.

24. A battery comprising:
a negative plate, the negative plate comprising a negative current collector coated with a negative active material, wherein the negative current collector comprises a conductive non-woven fabric.
